(19) United States
(12) Patent Application Publication
(10) Pub. No.: US 2015/0241774 A1
(43) Pub. Date: Aug. 27, 2015

(54) PHOTORESIST COMPOSITION AND METHOD OF MANUFACTURING A DISPLAY SUBSTRATE USING THE SAME

(71) Applicant: SAMSUNG DISPLAY CO., LTD., Yongin-City (KR)

(72) Inventors: Jeong-Won KIM, Seoul (KR); Jin-Ho JU, Seoul (KR); Dong-Min KIM, Hwaseong-si (KR); Seung-Ki KIM, Hwaseong-si (KR); Kwang-Woo PARK, Hwaseong-si (KR); Sun-Mi HAHM, Hwaseong-si (KR)

(21) Appl. No.: 14/525,684

(22) Filed: Oct. 28, 2014

(30) Foreign Application Priority Data
Feb. 26, 2014 (KR) 10-2014-0022523

(51) Int. Cl. G03F 7/038; H01L 29/66; H01L 27/12; H01L 21/467

(52) U.S. Cl. CPC G03F 7/0388; H01L 21/467; H01L 29/66969; H01L 27/127

(57) ABSTRACT

A photoresist composition may include a novolak resin, a diazide-based photo-sensitizer, and a solvent. The novolak resin may be prepared by a condensation reaction of a monomer mixture including a cresol mixture, xylenol, and salicylaldehyde. Methods of manufacturing a display substrate using the photoresist composition are also provided.

### CROSS-REFERENCE TO RELATED APPLICATION

Korean Patent Application No. 10-2014-0022523, filed on Feb. 26, 2014, in the Korean Intellectual Property Office, and entitled: “Photoresist Composition and Method of Manufacturing A Display Substrate Using the Same,” is incorporated by reference herein in its entirety.

### BACKGROUND

1. Technical Field

Exemplary embodiments relate to a photoresist composition. More particularly, exemplary embodiments relate to a photoresist composition and a method of manufacturing a display substrate using the photoresist composition.

2. Description of the Related Art

Generally, a display substrate that is used for a display device may include a thin film transistor that may serve as a switching element for driving a pixel unit, a signal line connected to the thin film transistor, and a pixel electrode. The signal line may include a gate line providing a gate signal and a data line crossing the gate line and providing a data signal.

### SUMMARY

A photoresist composition may include a novolak resin prepared by a condensation reaction of a monomer mixture including a cresol mixture, a xylenol, and salicylaldehyde; a diazide-based photo-sensitizer; and a solvent.

The photoresist composition may include about 5% to about 30% by weight of the novolak resin, about 2% to about 10% by weight of the diazide-based photo-sensitizer, and a remainder of the solvent.

The novolak resin may be represented by the following Chemical Formula 1:

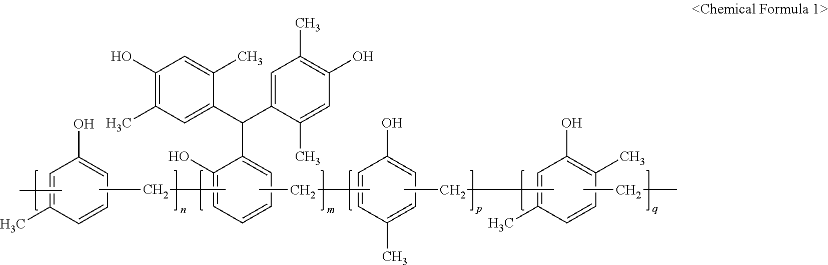

where n, m, p, and q represent mole fractions (%) and may be independently greater than 0, and a sum of n, m, p and q may be 100.

A weight average molecular weight of the novolak resin may range from about 10,000 to about 25,000 g/mol.

The monomer mixture may include about 20% to about 50% by weight of the cresol mixture, about 20% to about 30% by weight of the xylenol, and about 30% to about 50% by weight of salicylaldehyde.

The cresol mixture may include m-cresol and p-cresol in a weight ratio ranging from about 7:3 to about 3:7.

The diazide-based photo-sensitizer may include at least one of 2,3,4-trihydroxybenzophenone-1,2-naphthoquinonediazide-5-sulfonate and 2,3,4,4-tetrahydroxybenzophenone-1,2-naphthoquinonediazide-5-sulfonate.

The solvent may include at least one of a glycol ether, an ethylene glycol alkyl ether acetate, and a diethylene glycol.

The photoresist composition may further include about 0.1% to about 3% by weight of an additive including a surfactant and an adhesion enhancer.

A method of manufacturing a display substrate may include forming a gate metal pattern including a gate electrode on a base substrate, forming a gate insulation layer covering the gate metal pattern, forming an oxide semiconductor layer on the gate insulation layer, forming a source metal layer on the oxide semiconductor layer, coating a photoresist composition on the source metal layer to form a photoresist layer, developing the photoresist layer to form a first photoresist pattern; and etching the source metal layer and the oxide semiconductor layer using the first photoresist pattern as a mask to form a source metal pattern and an active pattern.

Etching the source metal layer and the oxide semiconductor layer may include wet-etching the source metal layer using the first photoresist pattern as a mask, partially removing the first photoresist pattern to form a second photoresist pattern partially exposing the source metal layer, and dry-etching the source metal layer and the oxide semiconductor layer using the second photoresist pattern as a mask to form the source metal pattern and the active pattern.

The source metal layer may have a triple-layered structure of molybdenum/aluminum/molybdenum.

The semiconductor layer may include amorphous silicon.

A method of manufacturing a display substrate may include forming a thin film transistor on a base substrate, the thin film transistor including a gate electrode, an active pattern, a source electrode, and a drain electrode, forming a first electrode electrically connected to the drain electrode, coating a photoresist composition on the first electrode to form a sacrificial layer, forming an insulation layer covering the sacrificial layer, forming a second electrode on the insulation layer, removing the sacrificial layer to form a cavity, and providing a liquid crystal layer in the cavity.

Removing the sacrificial layer may include exposing the sacrificial layer to light, and providing a developing solution to the sacrificial layer.

### BRIEF DESCRIPTION OF THE DRAWINGS

Features will become apparent to those of skill in the art by describing in detail exemplary embodiments with reference to the attached drawings in which:

FIGS. 1 to 8 illustrate cross-sectional views illustrating a method of manufacturing a display substrate according to an exemplary embodiment.

FIGS. 9 to 17 illustrate cross-sectional views illustrating a method of manufacturing a display substrate according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

Hereinafter, a photoresist composition according to an exemplary embodiment will be explained. Thereafter, a method of manufacturing a display substrate using the photoresist composition will be explained with reference to the accompanying drawings.

Photoresist Composition

A photoresist composition according to an exemplary embodiment may include a novolak resin, a diazide-based photo-sensitizer, and a solvent. For example, the photoresist composition may include about 5% to about 30% by weight of the novolak resin, about 2% to about 10% by weight of the diazide-based photo-sensitizer, and a remainder of the solvent.

The novolak resin may be alkali-soluble, and may be prepared from a condensation reaction of a monomer mixture including a cresol mixture, a xylenol, and salicylaldehyde. The cresol mixture may include m-cresol and p-cresol. The monomer mixture may further include formaldehyde.

The monomer mixture may include about 20% to about 50% by weight of the cresol mixture including m-cresol and p-cresol, about 20% to about 30% by weight of xylenol and about 30% to about 50% by weight of salicylaldehyde. In the cresol mixture, a weight ratio of m-cresol to p-cresol may be about 3:7 to 7:3.

For example, the novolak resin may be represented by the following Chemical Formula 1. A weight average molecular weight of the novolak resin may range from about 10,000 to about 25,000 g/mol.

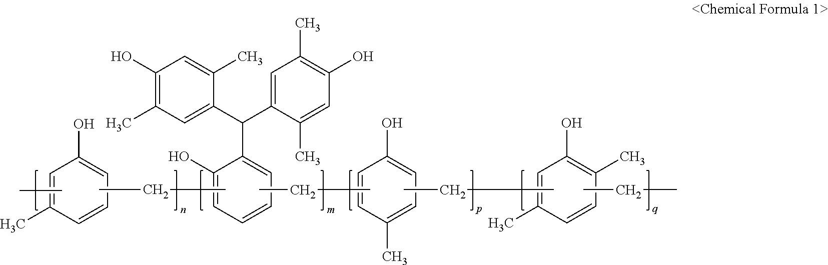

n, m, p and q independently represent a mole fraction (%) of a corresponding repeat unit in the novolak resin. In Chemical Formula 1, n, m, p and q may be independently greater than 0. In an implementation, a sum of n, m, p and q may be 100. For example, n may be 10 to 40, m may be 20 to 50, p may be 10 to 40, and q may be 5 to 30.

The novolak resin may be used with a novolak resin formed by a condensation reaction of m-cresol, p-cresol and formaldehyde.

When the amount of the novolak resin is less than about 5% by weight based on a total weight of the photoresist composition, the heat resistance of a photoresist pattern formed from the photoresist composition may be reduced. When the amount of the novolak resin is more than about 30% by weight, an adhesion ability, a sensitivity, a residual ratio, or the like, may be reduced. Thus, the amount of the novolak resin may range from about 5% to about 30% by weight based on a total weight of the photoresist composition. The amount of the novolak resin may also range from about 10% to about 25% by weight.

When the weight average molecular weight of the novolak resin is less than about 10,000 g/mol, the heat resistance of a photoresist pattern formed from the photoresist composition may be reduced. When the weight average molecular weight of the novolak resin is greater than about 25,000 g/mol, a residue may be formed after a developing process.

Examples of the diazide-based photo-sensitizer may include a quinone diazide compound. The quinone diazide compound may be obtained by reacting a naphthoquinone diazide sulfonate halogen compound with a phenol compound in the presence of a weak base.

Examples of the phenol compound may include 2,3,4-trihydroxybenzophenone, 2,4,6-trihydroxybenzophenone, 2,3,4,3′-tetrahydroxybenzophenone, 2,3,4,4′-tetrahydroxybenzophenone, tri(p-hydroxyphenyl)methane, 1,1,1-tri(p-hydroxyphenyl)ethane, 4,4′-[1-[4-[1-[4-hydroxyphenyl]-1-methylethyl]phenyl]ethylidene]diphenol, or the like, and may be used alone or in combination.

Examples of the naphthoquinone diazide sulfonate halogen compound may include 1,2-quinonediazide-4-sulfonic ester, 1,2-quinonediazide-5-sulfonic ester, 1,2-quinonediazide-6-sulfonic ester, or the like, and may be used alone or in combination.

Examples of the diazide-based photo-sensitizer may include 2,3,4-trihydroxybenzophenone-1,2-naphthoquinonediazide-5-sulfonate, 2,3,4,4-tetrahydroxybenzophenone-1,2-naphthoquinonediazide-5-sulfonate, or the like, and may be used alone or in combination.

When the amount of the diazide-based photo-sensitizer is less than about 2% by weight based on a total weight of the photoresist composition, a solubility of an unexposed portion may be increased, resulting in a photoresist pattern that is not completely formed. When the amount of the diazide-based photo-sensitizer is more than about 10% by weight, a solubility of an exposed portion may be reduced, resulting in an incomplete developing process. Thus, the amount of the diazide-based photo-sensitizer may range from about 2% to about 10% by weight. In particular, the amount of the diazide-based photo-sensitizer and may range from about 3% to about 8% by weight.

Examples of the solvent may include alcohols such as, for example, methanol and ethanol, ethers such as tetrahydrofuran, glycol ethers such as ethylene glycol monomethyl ether and ethylene glycol monoethyl ether, ethylene glycol alkyl ether acetates such as methyl cellosolve acetate, and ethyl cellosolve acetate, diethylene glycols such as diethylene glycol monomethyl ether, diethylene glycol monoethyl ether and diethylene glycol dimethyl ether, propylene glycol monoalkyl ethers such as propylene glycol methyl ether, propylene glycol ethyl ether, propylene glycol propyl ether and propylene glycol butyl ether, propylene glycol alkyl ether acetates such as propylene glycol methyl ether acetate, propylene glycol ethyl ether acetate, propylene glycol propyl ether acetate, and propylene glycol butyl ether acetate, propylene glycol alkyl ether propionates such as propylene glycol methyl ether propionate, propylene glycol ethyl ether propionate, propylene glycol propyl ether propionate, and propylene glycol butyl ether propionate, aromatic compounds such as toluene and xylene, ketones such as methyl ethyl ketone, cyclohexanone, and 4-hydroxy-4-methyl-2-pentanone, and ester compounds such as methyl acetate, ethyl acetate, propyl acetate, butyl acetate, ethyl 2-hydroxypropionate, methyl 2-hydroxy-2-methyl propionate, ethyl 2-hydroxy-2-methyl propionate, methyl hydroxyacetate, ethyl hydroxyacetate, butyl hydroxyacetate, methyl lactate, ethyl lactate, propyl lactate sulfate, butyl lactate, methyl 3-hydroxypropionate, ethyl 3-hydroxypropionate, propyl 3-hydroxypropionate, butyl 3-hydroxypropionate, methyl 2-hydroxy-3-methyl butanoate, methyl methoxy acetate, ethyl methoxy acetate, propyl methoxy acetate, butyl methoxy acetate, methyl ethoxy acetate, ethyl ethoxy acetate, propyl ethoxy acetate, butyl ethoxy acetate, methyl propoxy acetate, ethyl propoxy acetate, propyl propoxy acetate, butyl propoxy acetate, methyl butoxy acetate, ethyl butoxy acetate, propyl butoxy acetate, butyl butoxy acetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate, etc. Among the above examples, glycol ethers, ethylene glycol alkyl ether acetates, and diethylene glycols may be used in view of the solubility and reactivity of each of the components included in the photoresist composition.

In an exemplary embodiment, the amount of the solvent may range from about 60% to about 90% by weight based on a total weight of the photoresist composition.

In an embodiment, the photoresist composition may further include about 0.1% to about 3% by weight of an additive. For example, the additive may include a surfactant and an adhesion enhancer.

The surfactant may reduce interfacial tension between a substrate and a coating layer formed on the substrate from the photoresist composition so that the coating layer may be uniformly formed. Examples of the surfactant may include FZ-2110 (trade name, Dow Corning, U.S.), FZ-2122, BYK-345 (trade name, ALTANA, U.S.), BYK-346, BYK-34, or the like, and may be used alone or in combination.

The adhesion enhancer may increase adhesive strength between the photoresist composition and an inorganic substrate such as a glass substrate. Examples of the adhesion enhancer may include a silane coupling agent and a melamine cross-linker, which include an organic functional group and an inorganic functional group in a same compound.

Examples of the silane coupling agent may include KBM-303 (trade name, Shinetsu, Japan), KBM-403, KBE-402, KBE-40, or the like, and may be used alone or in combination. Examples of the melamine cross-linker may include MW-30M (trade name, VISION TECH, Korea), MX-706, or the like.

Method of Manufacturing a Display Substrate

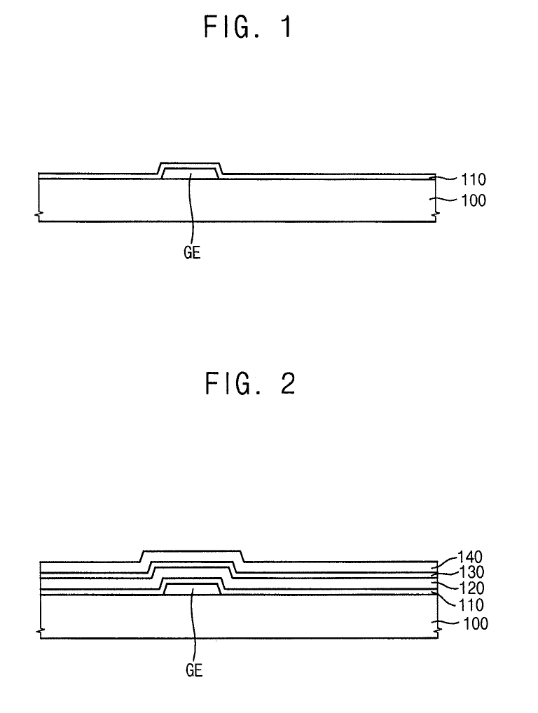

FIGS. 1 to 8 illustrate cross-sectional views illustrating a method of manufacturing a display substrate according to an exemplary embodiment.

Referring to FIG. 1, a gate metal pattern including a gate electrode GE may be formed on a base substrate 100. The gate metal pattern may further include a gate line connected to the gate electrode GE.

For example, a gate metal layer may be formed on the base substrate 100, and patterned to form the gate line and the gate electrode GE. Examples of the base substrate 200 may include a glass substrate, a quartz substrate, a silicon substrate, a plastic substrate, or the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different materials. For example, the gate metal layer may include a copper layer and a titanium layer disposed on and/or under the copper layer.

A gate insulation layer 110 may be formed to cover the gate line and the gate electrode GE. The gate insulation layer 110 may include silicon nitride, silicon oxide, or the like. The gate insulation layer 110 may have a single-layered structure or a multiple-layered structure. For example, the gate insulation layer 110 may include a lower insulation layer including silicon nitride and an upper insulation layer including silicon oxide.

Referring to FIG. 2, a semiconductor layer 120, an ohmic contact layer 130, and a source metal layer 140 may be sequentially formed on the gate insulation layer 110.

The semiconductor layer 120 may include amorphous silicon, and the ohmic contact layer 130 may include amorphous silicon into which n+ impurities may be implanted at a high concentration.

The source metal layer 140 may have a triple-layered structure of molybdenum/aluminum/molybdenum. In another embodiment, the source metal layer 140 may have a multiple-layered structure or a single-layered structure including a metal layer that can be dry-etched.

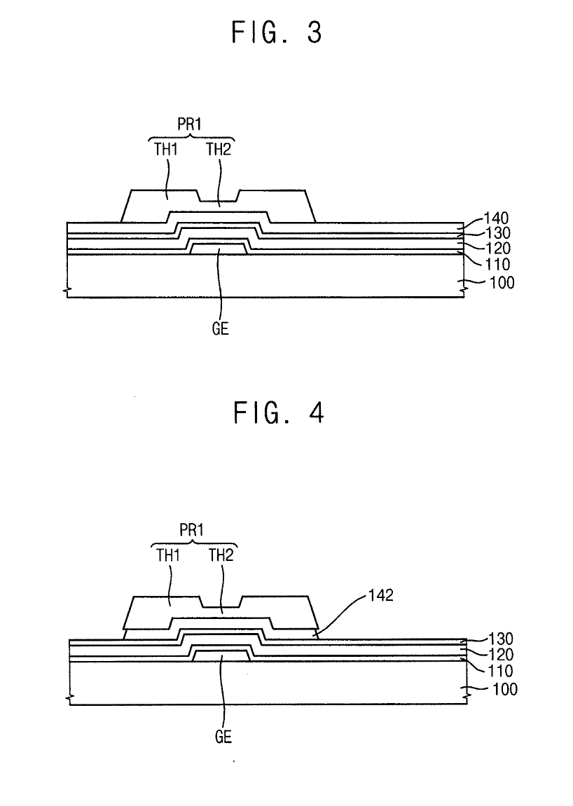

Referring to FIG. 3, a photoresist composition may be coated on the source metal layer 140 to form a photoresist layer. The photoresist layer may be patterned to form a first photoresist pattern PR1.

The photoresist composition may include a novolak resin, a diazide-based photo-sensitizer, and a solvent. For example, the photoresist composition may include about 5% to about 30% by weight of the novolak resin, about 2% to about 10% by weight of the diazide-based photo-sensitizer, and a remainder of the solvent. The novolak resin may be alkali-soluble and may be prepared by a condensation reaction of a monomer mixture including a cresol mixture, a xylenol, and salicylaldehyde. The cresol mixture may include m-cresol and p-cresol, and the monomer mixture may further include formaldehyde.

The monomer mixture may include about 20% to about 50% by weight of a cresol mixture including m-cresol and p-cresol, about 20% to about 30% by weight of a xylenol, and about 30% to about 50% by weight of salicylaldehyde. In the cresol mixture, a weight ratio of m-cresol to p-cresol may range from about 3:7 to about 7:3. The photoresist composition may be substantially the same as the previously-described photoresist composition. Thus, duplicative disclosure may be omitted.

The photoresist composition may be a positive-type, and the photoresist layer may be pre-baked, exposed to light, developed, and hard-baked to from the first photoresist pattern PR1. A temperature for pre-baking may range from about 80° C. to about 120° C., and a temperature for hard-baking may range from about 120° C. to about 150° C.

The first photoresist pattern PR1 may overlap with the gate electrode GE, and include a thickness gradient. For example, the first photoresist pattern PR1 may include a first thickness portion TH1 and a second thickness portion TH2 that is thinner than the first thickness portion TH1. The second thickness portion TH2 may overlap with the gate electrode GE.

The first photoresist pattern PR1 may have an improved heat resistance. Thus, a profile of the first photoresist pattern PR1 may be maintained in a hard-baking process, and the reliability of the photolithography process may be improved.

Referring to FIG. 4, the source metal layer 140 may be patterned by using the first photoresist pattern PR1 as a mask to form a source metal pattern 142. The source metal pattern may include a data line crossing the gate line. In the exemplary embodiments, the source metal layer 140 may be etched through a wet-etching process using an etchant. Accordingly, an upper surface of the ohmic contact layer 130 may be exposed.

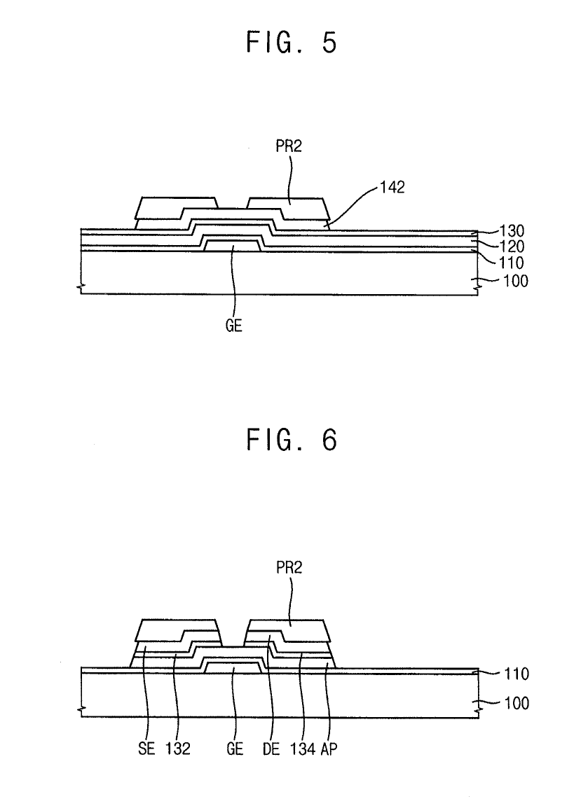

Referring to FIG. 5, the first photoresist pattern PR1 may be partially removed, for example, through an ashing process. Thus, the second thickness portion TH2 may be removed, and the first thickness portion TH1 may partially remain to form the second photoresist pattern PR2. The second photoresist pattern PR2 may expose a portion of the source metal pattern 142.

Referring to FIG. 6, an exposed portion of the source metal pattern 142 and a portion of the ohmic contact layer 130 may be removed through a dry-etching process to form a source electrode SE and a drain electrode DE. Furthermore, the ohmic contact layer 130 and the semiconductor layer 120 in an area uncovered by the photoresist pattern may be removed to form an active pattern AP and an ohmic contact pattern disposed on the active pattern AP. The ohmic contact pattern may include a first ohmic contact pattern 132 contacting the source electrode SE and a second ohmic contact pattern 134 contacting the drain electrode DE.

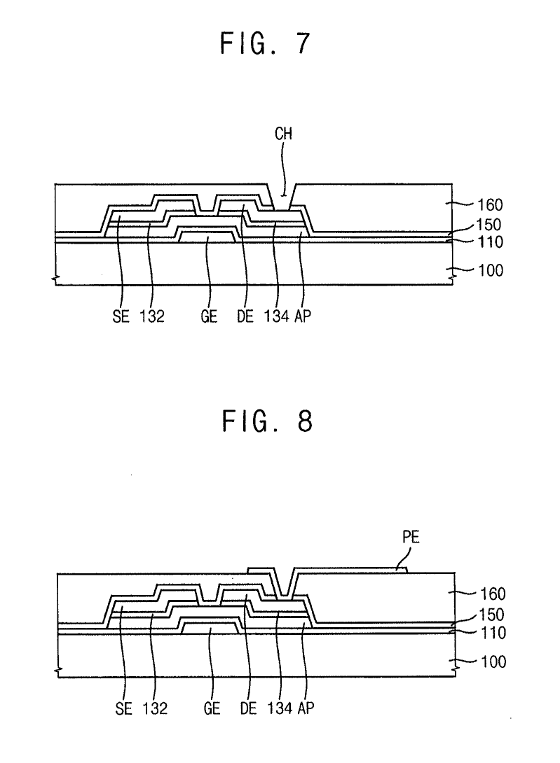

Referring to FIG. 7, a passivation layer 150 may be formed to cover the source electrode SE and the drain electrode DE. An organic insulation layer 160 may be formed on the passivation layer 150. A contact hole CH may be formed through the passivation layer 150 and the organic insulation layer 160 to expose the drain electrode DE.

The passivation layer 150 may include an inorganic insulation material such as silicon oxide, silicon nitride, or the like. The organic insulation layer 160 may include an organic insulation material to flatten the substrate.

Referring to FIG. 8, a conductive layer may be formed on the organic insulation layer 160 and patterned to form a pixel electrode PE including a conductive metal oxide such as indium tin oxide, indium zinc oxide, or the like.

The display substrate may be used for a liquid crystal display apparatus or an organic electroluminescent display apparatus.

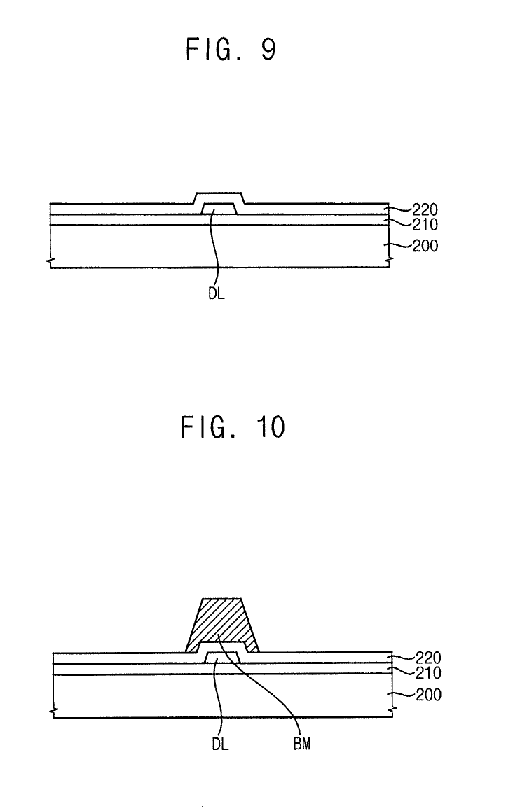

FIGS. 9 to 17 are cross-sectional views illustrating a method of manufacturing a display substrate according to an exemplary embodiment.

Referring to FIG. 9, a gate metal pattern including a gate line and a gate electrode may be formed on a base substrate 200. A gate insulation layer 210 may be formed to cover the gate metal pattern. An active pattern overlapping with the gate electrode may be formed on the gate insulation layer 210. A source metal pattern including a source electrode, a drain electrode, and a data line DL may be formed. A passivation layer 220 may be formed to cover the source metal pattern.

The gate electrode, the source electrode, the drain electrode, and the active pattern may constitute a thin film transistor.

Referring to FIG. 10, a black matrix BM overlapping with the data line DL may be formed on the passivation layer 220. The black matrix BM may further overlap with the gate line. The black matrix BM may be formed from a photoresist composition including a pigment such as carbon black or the like.

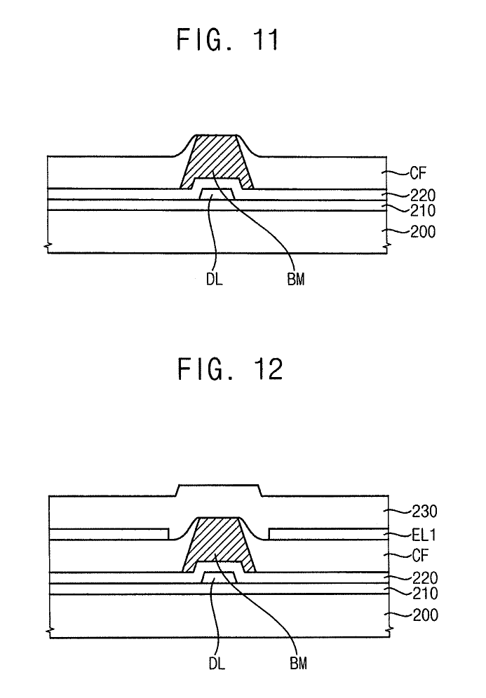

Referring to FIG. 11, a color filter CF may be formed on the passivation layer 220. The color filter CF may be formed through an ink-jet process or a photolithography process. The color filter CF may partially cover the black matrix BM.

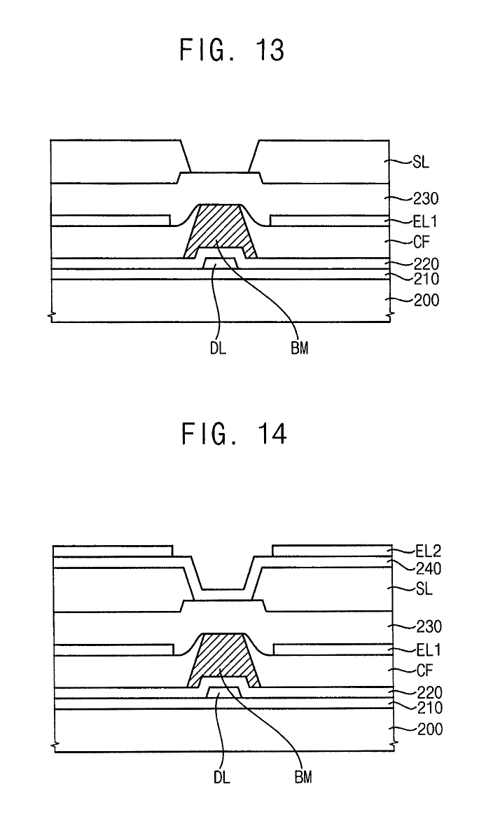

Referring to FIG. 12, a first electrode EL1 may be formed on the color filter CF. The first electrode EL1 may be a pixel electrode electrically connected to the drain electrode. The first electrode EL1 may include a conductive metal oxide such as indium tin oxide, indium zinc oxide, or the like.

A lower insulation layer 230 may be farmed on the first electrode EL1. The lower insulation layer 230 may include an organic insulation material or an inorganic insulation material.

Referring to FIG. 13, a photoresist composition may be coated on the lower insulation layer 230 to form a sacrificial layer SL. The sacrificial layer SL may include a plurality of pattern arrays overlapping with the first electrode EL1.

The photoresist composition may include a novolak resin, a diazide-based photo-sensitizer, and a solvent. For example, the photoresist composition may include about 5% to about 30% by weight of the novolak resin, about 2% to about 10% by weight of the diazide-based photo-sensitizer, and a remainder of the solvent. The novolak resin may be alkali-soluble, and may be prepared by a condensation reaction of a monomer mixture including a cresol mixture, a xylenol, and salicylaldehyde. The cresol mixture may include m-cresol and p-cresol, and the monomer mixture may further include formaldehyde.

The monomer mixture may include about 20% to about 50% by weight of a cresol mixture including m-cresol and p-cresol, about 20% to about 30% by weight of a xylenol, and about 30% to about 50% by weight of salicylaldehyde. In the cresol mixture, a weight ratio of m-cresol to p-cresol may range from about 3:7 to about 7:3. The photoresist composition may be substantially the same as the previously explained photoresist composition. Thus, duplicative disclosure may be omitted.

The photoresist composition may be pre-baked, exposed to light, developed, and hard-baked to from the sacrificial layer SL. A temperature for pre-baking may range from about 80° C. to about 120° C., and a temperature for hard-baking may range from about 120° C. to about 150° C.

Referring to FIG. 14, an upper insulation layer 240 covering to the sacrificial layer SL may be formed, and a second electrode EL2 may be formed on the upper insulation layer 240.

The upper insulation layer 240 may include an organic insulation material or an inorganic insulation material. The second electrode EL2 may include a conductive metal oxide such as indium tin oxide, indium zinc oxide, or the like.

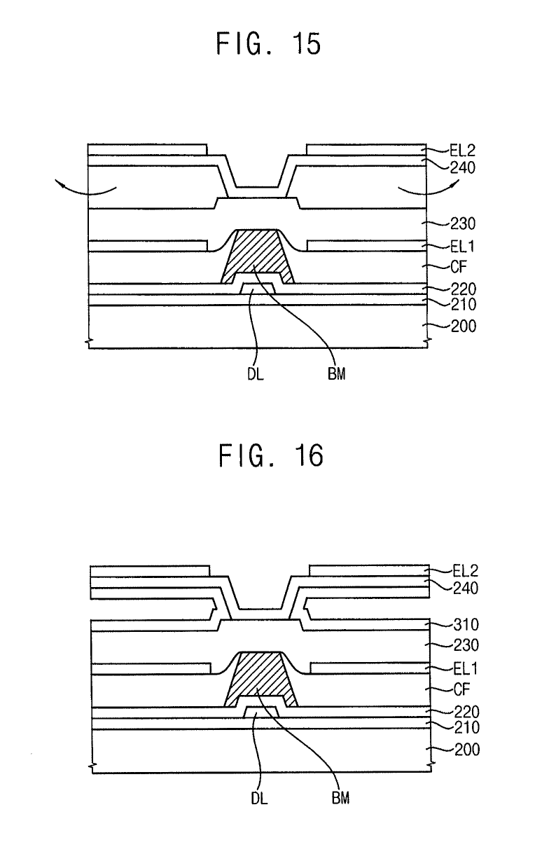

Referring to FIG. 15, the sacrificial layer SL may be removed by a developing solution.

For example, a portion of the upper insulation layer 240 may be removed to form a developer injection hole in order to remove the sacrificial layer SL. In the process of forming the developer injection hole, the sacrificial layer SL may be exposed to light. The photoresist composition may be positiv-type. Thus, a solubility of the photoresist composition may be increased by light-exposure so that the sacrificial layer SL including the photoresist composition may be removable by the developing solution.

When the sacrificial layer SL is removed, a cavity may be formed where the sacrificial layer SL was disposed. The cavity may have a tunnel shape.

Referring to FIG. 16, an alignment layer 310 may be formed in the cavity. An alignment composition may be provided into the cavity to form the alignment layer 310.

The alignment composition may include an alignment material such as polyimide and a solvent. When the alignment composition is provided to an area adjacent to the cavity, the alignment composition may move into the cavity though the developer injection hole by capillary action.

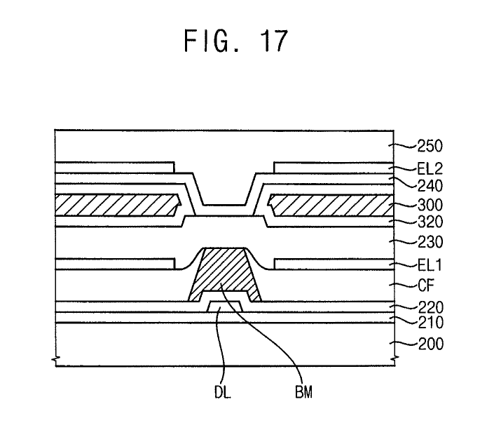

Referring to FIG. 17, a liquid crystal composition may be injected into the cavity to form a liquid crystal layer 300. A protective layer 500 may be formed on the upper insulation layer 240 and the second electrode EL2. A polarizing member may be disposed on the protective layer 500 and under the base substrate 200.

According to the embodiment, the sacrificial layer SL may have a high heat resistance. Thus, a profile of the sacrificial layer SL may be maintained even in a high temperature process, and a cavity formed from removing the sacrificial layer SL may have a profile with a large taper angle. Thus, a liquid crystal texture that may be formed in a peripheral area of the cavity may be reduced or prevented.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples

### Photoresist Composition

About 20 g of a novolak resin were formed by a condensation reaction of xylenol, salicylaldehyde, and a remainder of a cresol mixture according to the following Table 1. The novolak resin, about 5 g of 2,3,4,4-tetrahydroxybenzophenone-1,2-naphthoquinonediazide-5-sulfonate, and about 70 g of propyleneglycol methylether acetate, were mixed to prepare a photoresist composition. A weight average molecular weight of the novolak resin was about 20,000 g/mol. The cresol mixture included m-cresol and p-cresol in a weight ratio of 5:5.

TABLE 1

| | Xylenol | Salicylaldehyde |
|---|---|---|
| | (% by weight) | (% by weight) |
| Example 1 | 10 | 10 |
| Example 2 | 10 | 30 |
| Example 3 | 10 | 50 |
| Example 4 | 20 | 10 |
| Example 5 | 20 | 30 |
| Example 6 | 20 | 50 |
| Example 7 | 30 | 10 |
| Example 8 | 30 | 30 |
| Example 9 | 30 | 50 |
| Example 10 | 10 | 60 |
| Example 11 | 30 | 60 |
| Example 12 | 40 | 10 |
| Example 13 | 40 | 50 |
| Comparative Example 1 | 0 | 10 |
| Comparative Example 2 | 0 | 50 |
| Comparative Example 3 | 10 | 0 |
| Comparative Example 4 | 30 | 0 |
| Comparative Example 5 | 40 | 0 |

Evaluation 1—Residue Ratio

Each of the photoresist compositions of Examples 1 to 13 and Comparative Examples 1 to 5 was spin-coated on a silicon wafer to form a coating layer. The coating layer was vacuum-chamber-dried under a pressure of about 0.5 torr, and heated at about 110° C. for about 150 seconds to form a film having a thickness of about 2.0 μm. A tetramethylammonium hydroxide water solution was provided to the film for about 75 seconds. A thickness of the film was measured, before and after the tetramethylammonium hydroxide water solution was provided to obtain a residue ratio (thickness after developing/thickness before developing).

Evaluation 2—Heat Resistance

Each of the photoresist compositions of Examples 1 to 13 and Comparative Examples 1 to 5 was spin-coated on a silicon wafer to form a coating layer. The coating layer was vacuum-chamber-dried under a pressure of about 0.5 torr, and heated at about 110° C. for about 150 seconds to form a film having a thickness of about 2.0 μm. After the film was exposed to light, a tetramethylammonium hydroxide water solution was provided to the film for about 75 seconds to form a photoresist pattern. A temperature at which reflow of the photoresist pattern was observed when the photoresist pattern was heated for about 150 seconds was measured.

Evaluation 3—Residue

Each of the photoresist compositions of Examples 1 to 13 and Comparative Examples 1 to 5 was spin-coated on a silicon wafer to form a coating layer. The coating layer was vacuum-chamber-dried under a pressure of about 0.5 torr, and heated at about 110° C. for about 150 seconds to form a film having a thickness of about 2.0 μm. After the film was exposed to light, a tetramethylammonium hydroxide water solution was provided to the film for about 75 seconds to form a photoresist pattern. Then, it was observed whether a residue remained in a light-exposed portion. “X” indicates that no residue was observed. “O” indicates that residue was observed.

Results obtained from Evaluations 1 to 3 are shown in the following Table 2.

TABLE 2

| | | Reflow | |
|---|---|---|---|
| | Residue ratio (%) | temperature (° C.) | Residue |
| Example 1 | 94 | 135 | X |
| Example 2 | 91 | 140 | X |
| Example 3 | 86 | 140 | X |
| Example 4 | 96 | 140 | X |
| Example 5 | 93 | 145 | X |
| Example 6 | 88 | 145 | X |
| Example 7 | 98 | 140 | X |
| Example 8 | 96 | 145 | X |
| Example 9 | 91 | 145 | X |
| Example 10 | 67 | 140 | X |
| Example 11 | 69 | 150 | X |
| Example 12 | 99 | 140 | ◯ |
| Example 13 | 81 | 150 | ◯ |
| Comparative Example 1 | 90 | 120 | X |
| Comparative Example 2 | 80 | 125 | X |
| Comparative Example 3 | 95 | 120 | X |
| Comparative Example 4 | 99 | 125 | X |
| Comparative Example 5 | 99 | 125 | ◯ |

About 20 g of a mixture of a first novolak resin and a second novolak resin mixed according to the following Table 3, about 5 g of 2,3,4,4-tetrahydroxybenzophenone-1,2-naphthoquinonediazide-5-sulfonate, and about 70 g of propyleneglycol methylether acetate were mixed to prepare a photoresist composition. The first novolak resin was the same as the novolak resin of Example 5. The second novolak resin was prepared from reaction of formaldehyde and a cresol mixture including m-cresol and p-cresol in a weight ratio of about 4:6. A weight average molecular weight of the second novolak resin was about 10,000 g/mol.

TABLE 3

| | First Novolak Resin:Second Novolak Resin (weight ratio) |
|---|---|
| Example 14 | 10:0 |
| Example 15 | 8:2 |
| Example 16 | 5:5 |
| Example 17 | 2:8 |
| Comparative | 0:10 |
| Example 6 | |

Evaluation 4—Heat Resistance

Each of the photoresist compositions of Examples 14 to 17 and Comparative Examples 6 was spin-coated on a silicon wafer to form a coating layer. The coating layer was vacuum-chamber-dried under a pressure of about 0.5 torr, and heated at about 110° C. for about 150 seconds to form a film having a thickness of about 2.0 μm. After the film was exposed to light, a tetramethylammonium hydroxide water solution was provided to the film for about 75 seconds to form a photoresist pattern. A temperature at which reflow of the photoresist pattern was observed when the photoresist pattern was heated for about 150 seconds was measured. Results obtained are shown in the following Table 4.

TABLE 4

| | Reflow temperature (° C.) |
|---|---|
| Example 14 | 145 |
| Example 15 | 140 |
| Example 16 | 135 |
| Example 17 | 130 |
| Comparative | 125 |
| Example 6 | |

Referring the results of the Evaluations, it can be noted that exemplary photoresist compositions may increase a heat resistance of a photoresist pattern. However, when the amount of salicylaldehyde is excessive in a monomer mixture, a residue ratio may be reduced. Furthermore, when the amount of xylenol is excessive in the monomer mixture, a residue may remain in a removed portion. Thus, the amount of salicylaldehyde may range from about 30% to about 50% by weight in the monomer mixture, and the amount of xylenol may range from about 20% to about 30% by weight in the monomer mixture.

By way of summation and review, a photolithography process may be used for forming a thin film transistor, a signal line, and a pixel electrode. According to the photolithography process, a photoresist pattern may be formed on an object layer, and the object layer may be patterned by using the photoresist pattern as a mask to form a desired pattern. In the photolithography process, the object layer may be dry-etched or wet-etched.

A flexibility of a photoresist pattern may increase at a high temperature so that a profile of the photoresist pattern may be changed. For example, when the object layer is dry-etched, a temperature of a chamber where a dry-etching is performed may increase, thereby causing reflow of a photoresist pattern. Thus, the reliability of the photolithography process may be reduced.

In contrast, exemplary embodiments provide a photoresist composition capable of improving a heat resistance of a photoresist pattern. Exemplary embodiments further provide a method of manufacturing a display substrate using the photoresist composition.

According exemplary embodiments, the photoresist composition of exemplary embodiments may form a photoresist pattern having a high heat resistance, thereby preventing the photoresist pattern from reflowing, and the photoresist pattern may maintain its profile even at a high temperature during, for example, a hard-baking process, a dry-etching process, or the like. Thus, an active protrusion may be prevented, and a channel length of a thin film transistor may be substantially reduced, thereby improving the electrical characteristics of the thin film transistor.

Furthermore, if the photoresist composition is used to form a sacrificial layer of a display substrate including a cavity having a tunnel shape, a liquid crystal texture that may be caused in a peripheral area of the cavity may be reduced or prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist composition, comprising:
a novolak resin prepared by a condensation reaction of a monomer mixture including a cresol mixture, a xylenol, and salicylaldehyde;
a diazide-based photo-sensitizer; and
a solvent.

2. The photoresist composition as claimed in claim 1, wherein the photoresist composition includes about 5% to about 30% by weight of the novolak resin, about 2% to about 10% by weight of the diazide-based photo-sensitizer, and a remainder of the solvent.

3. The photoresist composition as claimed in claim 2, wherein the novolak resin is represented by the following Chemical Formula 1: 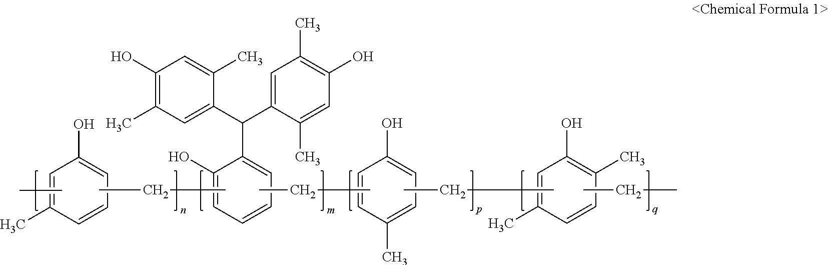
wherein n, m, p, and q represent mole fractions (%) and are independently greater than 0, and a sum of n, m, p and q is 100.

4. The photoresist composition as claimed in claim 2, wherein a weight average molecular weight of the novolak resin ranges from about 10,000 to about 25,000 g/mol.

5. The photoresist composition as claimed in claim 2, wherein the monomer mixture includes about 20% to about 50% by weight of the cresol mixture, about 20% to about 30% by weight of the xylenol, and about 30% to about 50% by weight of salicylaldehyde.

6. The photoresist composition as claimed in claim 5, wherein the cresol mixture includes m-cresol and p-cresol in a weight ratio ranging from about 7:3 to about 3:7.

7. The photoresist composition as claimed in claim 2, wherein the diazide-based photo-sensitizer includes at least one of 2,3,4-trihydroxybenzophenone-1,2-naphthoquinonediazide-5-sulfonate and 2,3,4,4-tetrahydroxybenzophenone-1,2-naphthoquinonediazide-5-sulfonate.

8. The photoresist composition as claimed in claim 2, wherein the solvent includes at least one of a glycol ether, an ethylene glycol alkyl ether acetate, and a diethylene glycol.

9. The photoresist composition as claimed in claim 2, further comprising about 0.1% to about 3% by weight of an additive including a surfactant and an adhesion enhancer.

10. A method of manufacturing a display substrate, the method comprising:
forming a gate metal pattern including a gate electrode on a base substrate;
forming a gate insulation layer covering the gate metal pattern;
forming an oxide semiconductor layer on the gate insulation layer;
forming a source metal layer on the oxide semiconductor layer;
coating the photoresist composition as claimed in claim 1 on the source metal layer to form a photoresist layer;
developing the photoresist layer to form a first photoresist pattern; and
etching the source metal layer and the oxide semiconductor layer using the first photoresist pattern as a mask to form a source metal pattern and an active pattern.

11. The method as claimed in claim 10, wherein etching the source metal layer and the oxide semiconductor layer includes:
wet-etching the source metal layer using the first photoresist pattern as a mask;
partially removing the first photoresist pattern to form a second photoresist pattern partially exposing the source metal layer; and
dry-etching the source metal layer and the oxide semiconductor layer using the second photoresist pattern as a mask to form the source metal pattern and the active pattern.

12. The method as claimed in claim 11, wherein the source metal layer has a triple-layered structure of molybdenum/aluminum/molybdenum.

13. The method as claimed in claim 12, wherein the semiconductor layer includes amorphous silicon.

14. A method of manufacturing a display substrate, the method comprising:
forming a thin film transistor on a base substrate, the thin film transistor including a gate electrode, an active pattern, a source electrode, and a drain electrode;
forming a first electrode electrically connected to the drain electrode;
coating the photoresist composition as claimed in claim 1 on the first electrode to form a sacrificial layer;
forming an insulation layer covering the sacrificial layer;
forming a second electrode on the insulation layer;
removing the sacrificial layer to form a cavity; and
providing a liquid crystal layer in the cavity.

15. The method as claimed in claim 14, wherein removing the sacrificial layer includes:
exposing the sacrificial layer to light; and
providing a developing solution to the sacrificial layer.

16. The photoresist composition as claimed in claim 1, wherein the monomer mixture further includes formaldehyde.
